(19) United States
(12) Patent Application Publication
(10) Pub. No.: US 2018/0366549 A1
(43) Pub. Date: Dec. 20, 2018

(54) SEMICONDUCTOR DEVICE AND METHOD OF MANUFACTURING A SEMICONDUCTOR DEVICE

(71) Applicant: FUJI ELECTRIC CO., LTD., Kawasaki-shi (JP)

(72) Inventors: Takahito KOJIMA, Matsumoto-city (JP); Takashi TSUJI, Matsumoto-city (JP)

(73) Assignee: FUJI ELECTRIC CO., LTD., Kawasaki-shi (JP)

(21) Appl. No.: 15/989,399

(22) Filed: May 25, 2018

(30) Foreign Application Priority Data
Jun. 14, 2017 (JP) 2017-116508

(51) Int. Cl. H01L 29/16; H01L 29/66; H01L 29/423; H01L 29/08

(52) U.S. Cl. CPC H01L 29/1608; H01L 29/0847; H01L 29/4236; H01L 29/66068

(57) ABSTRACT

A semiconductor device includes an n-type silicon carbide epitaxial layer formed on an n⁺-type silicon carbide semiconductor substrate, p⁺-type base regions formed in the n-type silicon carbide epitaxial layer, a dense n-type region formed in the n-type silicon carbide epitaxial layer, a p-type base layer formed on the dense n-type region, an n⁺-type source region and a p⁺⁺-type contact region formed in the p-type base layer, a trench penetrating the p-type base layer in a depth direction of a part of one of the p⁺-type base regions, and a gate electrode formed on a gate insulating film in the trench. The n⁺-type source region is formed using two dopant types, phosphorus and carbon. A dose amount D_{C} of carbon satisfies 0.7≤D_{C}/Dₚ≤1.3 with respect to a dose amount Dₚ of phosphorus. An impurity concentration of the n⁺-type source region ranges from 10¹⁸ to 10²¹.

### CROSS REFERENCE TO RELATED APPLICATIONS

This application is based upon and claims the benefit of priority of the prior Japanese Patent Application No. 2017-116508, filed on Jun. 14, 2017, the entire contents of which are incorporated herein by reference.

### BACKGROUND OF THE INVENTION

### 1. Field of the Invention

Embodiments of the invention relate to a semiconductor device having a trench structure such as a vertical MOSFET using a wide bandgap semiconductor material and a method of manufacturing a semiconductor device.

### 2. Description of the Related Art

Among vertical metal-oxide-semiconductor field-effect transistors (MOSFETs), a trench type in which a channel is formed orthogonal to a substrate surface enables cell density to be increased to a greater extent than a planar type in which a channel is formed parallel to the substrate surface. Therefore, the trench type enables current density per unit area to be increased and is advantageous in terms of cost.

### SUMMARY OF THE INVENTION

According to an embodiment of the present invention, a semiconductor device includes a first silicon carbide semiconductor layer of a first conductivity type formed on a surface of a silicon carbide semiconductor substrate of the first conductivity type having a high impurity concentration, i.e., a high-concentration silicon carbide semiconductor substrate of the first conductivity type, the first silicon carbide semiconductor layer having a low impurity concentration; a first base region of a second conductivity type selectively provided in a surface of the first silicon carbide semiconductor layer; a second silicon carbide semiconductor layer of the second conductivity type formed on the first silicon carbide semiconductor layer; a source region of the first conductivity type and a contact region of the second conductivity type formed selectively in a surface layer of the second silicon carbide semiconductor layer; a trench formed penetrating the second silicon carbide semiconductor layer; and a gate electrode formed in the trench, on a gate insulating film. The source region is formed using two dopant types that are phosphorus and carbon. A dose amount D_{C} of carbon satisfies 0.7≤D_{C}/Dₚ≤1.3 with respect to a dose amount Dₚ of phosphorus. An impurity concentration of the source region being on an order of 10¹⁸ to 10²¹.

In the embodiment, the semiconductor device further includes a first-conductivity-type region of the first conductivity type formed between the first silicon carbide semiconductor layer and the second silicon carbide semiconductor layer, an impurity concentration of the first-conductivity-type region being higher than that of the first silicon carbide semiconductor layer. A lower end of the first base region and a lower end of the trench are in the first-conductivity-type region.

In the embodiment, the source region contains a higher ratio of carbon than silicon.

In the embodiment, the source region is formed using two dopant types that are nitrogen and silicon, a dose amount D_{Si} of silicon satisfying 0.7≤D_{Si}/D_{N}≤1.3 with respect to a dose amount D_{N} of nitrogen. The impurity concentration of the source region is on the order of 10¹⁸ to 10²¹.

In the embodiment, the source region contains a higher ratio of silicon than carbon.

In the embodiment, the semiconductor device further includes a second base region of the second conductivity type provided at a lower end of the trench, an impurity concentration of the second base region being a same as an impurity concentration of the first base region. A width Wbp of the first base region is narrower than a width Wtbp of the second base region (Wbp<Wtbp).

According to another embodiment of the present invention a method of manufacturing a semiconductor device, includes forming a first silicon carbide semiconductor layer of a first conductivity type on a surface of a high-concentration silicon carbide semiconductor substrate of the first conductivity type, the first silicon carbide semiconductor layer having a low impurity concentration; selectively forming a first base region of a second conductivity type and a second base region of the second conductivity type in a surface layer of the first silicon carbide semiconductor layer; forming a second silicon carbide semiconductor layer of the second conductivity type on a surface of the first silicon carbide semiconductor layer, the second silicon carbide semiconductor layer having a low impurity concentration; selectively forming a source region of the first conductivity type in a surface of the second silicon carbide semiconductor layer; forming a contact region of the second conductivity type in the surface of the second silicon carbide semiconductor layer, the contact region being adjacent to the source region; forming a trench at a part of the source region in the surface of the second silicon carbide semiconductor layer, the trench penetrating the second silicon carbide semiconductor layer, the trench being shallower than the second base region; forming a gate insulating film on a bottom and sides of the trench; forming a gate electrode on the gate insulating film; forming an interlayer insulating film on the gate electrode; forming a source electrode on surfaces of the source region and the contact region; and forming a drain electrode on a rear surface of the high-concentration silicon carbide substrate. The source region is formed using two dopant types that are phosphorus and carbon. A dose amount D_{C} of carbon satisfies 0.7≤D_{C}/Dₚ≤1.3 with respect to a dose amount Dₚ of phosphorus. An impurity concentration of the source region is on an order of 10¹⁸ to 10²¹.

In the embodiment, the source region is formed using two dopant types that are nitrogen and silicon. A dose amount D_{Si} of silicon satisfies 0.7≤D_{Si}/D_{N}≤1.3 with respect to a dose amount D_{N} of nitrogen. The impurity concentration of the source region is on an order of 10¹⁸ to 10²¹.

In the embodiment, the method further includes forming a first-conductivity-type region of the first conductivity type, the first-conductivity-type region being formed deeper than the first base region and the second base region from the surface of the second silicon carbide semiconductor layer.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a configuration of the semiconductor device according to the embodiment;

FIG. 2 is a graph depicting a relationship of drain saturation current (IDSS) and the ratio of Dₚ and D_{C} of the semiconductor device according to the embodiment;

FIG. 3 is a cross-sectional view of the semiconductor device according to the embodiment during manufacture;

FIG. 4 is a cross-sectional view of the semiconductor device according to the embodiment during manufacture;

FIG. 5 is a cross-sectional view of the semiconductor device according to the embodiment during manufacture;

FIG. 6 is a cross-sectional view of the semiconductor device according to the embodiment during manufacture;

FIG. 7 is a cross-sectional view of the semiconductor device according to the embodiment during manufacture; and

FIG. 8 is a cross-sectional view of the semiconductor device according to the embodiment during manufacture.

### DETAILED DESCRIPTION OF THE INVENTION

A problem associated with a related technique will be discussed. It has been reported that crystal defects are formed by ion implantation using high accelerating voltage when a source part of a silicon carbide semiconductor device is formed and by 1500 degree C. or higher annealing for activating implanted ions. These crystal defects affect leak current of a MOS device (for example, refer to Onda, Shoichi, et al, “Transmission electron microscope study of a threading dislocation with b=+<1-100> and its effect on leakage in a 4H-SiC MOSFET”, Philosophical Magazine Letters, Volume 93, Issue 8, 2013).

Similarly to Onda, Shoichi, et al, the inventors confirmed that leak current is generated when using a 4H-SiC substrate to fabricate a semiconductor device.

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal In the description of the embodiments below and the accompanying drawings, main portions that are identical will be given the same reference numerals and will not be repeatedly described. Further, in the present description, when Miller indices are described, “−” means a bar added to an index immediately after the “−”, and a negative index is expressed by prefixing “−” to the index.

A semiconductor device according to an embodiment of the present invention is configured using a wide bandgap semiconductor material. In the embodiment, a MOS-type silicon carbide semiconductor device fabricated using silicon carbide (SiC) as a wide bandgap semiconductor material will be described as an example.

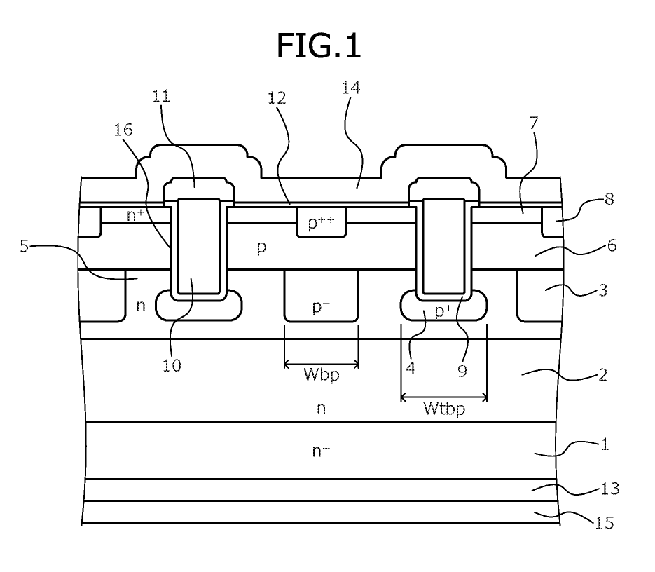

FIG. 1 is a cross-sectional view of a configuration of the semiconductor device according to the embodiment. As depicted in FIG. 1, in the silicon carbide semiconductor device according to the embodiment, on a first main surface, for example, a (0001) plane (Si face) of an n⁺-type silicon carbide substrate 1, an n-type silicon carbide epitaxial layer 2 is deposited.

The n⁺-type silicon carbide substrate 1 is a silicon carbide single-crystal substrate doped with, for example, nitrogen (N). The n-type silicon carbide epitaxial layer 2 is a low-concentration n-type drift layer doped with, for example, nitrogen. An impurity concentration of the n-type silicon carbide epitaxial layer 2 is lower than an impurity concentration of the n⁺-type silicon carbide substrate 1. In a first main surface side of the n-type silicon carbide epitaxial layer 2, a dense n-type region 5 is formed. An impurity concentration of the dense n-type region 5 is lower than the impurity concentration of the n⁺-type silicon carbide substrate 1 and higher than the impurity concentration of the n-type silicon carbide epitaxial layer 2, for example, the dense n-type region 5 is doped with nitrogen. Hereinafter, a silicon carbide semiconductor base is the n⁺-type silicon carbide substrate 1 alone, or the n⁺-type silicon carbide substrate 1 and the n-type silicon carbide epitaxial layer 2, or the n⁺-type silicon carbide substrate 1, the n-type silicon carbide epitaxial layer 2 and a p-type base layer collectively.

As depicted in FIG. 1, on a surface of a first side (rear surface of the silicon carbide semiconductor base) of the n⁺-type silicon carbide substrate 1 opposite a second side of the n⁺-type silicon carbide substrate 1 facing the n-type silicon carbide epitaxial layer 2, a rear electrode 13 is provided. The rear electrode 13 constitutes a drain electrode.

In a first main surface side of the silicon carbide semiconductor base, a trench structure is formed. In particular, a trench 16 penetrates a p-type base layer 6 from a surface of a first side (the first main surface side of the silicon carbide semiconductor base) of the p-type base layer 6 opposite a second side of the p-type base layer 6 facing toward the n⁺-type silicon carbide substrate 1. Further, along a surface of the trench 16, a gate insulating film 9 is formed at a bottom and sides of the trench 16. A gate electrode 10 insulated from the n-type silicon carbide epitaxial layer 2 and the p-type base layer 6 by the gate insulating film 9 is formed in the trench 16. A part of the gate electrode 10 may protrude outside the trench 16.

In a surface layer on a first side (the first main surface side of the silicon carbide semiconductor base) of the n-type silicon carbide epitaxial layer 2 opposite a second side of the n-type silicon carbide epitaxial layer 2 facing the n⁺-type silicon carbide substrate 1, a first p⁺-type base region 3 and a second p⁺-type base region 4 are selectively provided. A width of the first p⁺-type base region 3 is Wbp and a width of the second p⁺-type base region 4 is Wtbp, where Wbp<Wtbp is assumed. The second p⁺-type base region 4 is formed under the trench 16. The width (Wtbp) of the second p⁺-type base region 4 is at least a width of the trench 16. The first p⁺-type base region 3 and the second p⁺-type base region 4 are, for example, doped with aluminum.

A part of the first p⁺-type base region 3 may extend toward the trench 16, thereby forming a structure in which the first p⁺-type base region 3 is connected to the second p⁺-type base region 4. A reason for this is as follows. Holes generated when avalanche breakdown occurs at a junction part of the n-type silicon carbide epitaxial layer 2 and the second p⁺-type base region 4 under the gate electrode 10 are efficiently migrated to a source electrode 12, whereby load on a gate oxide film is reduced and reliability is increased.

The p-type base layer 6 of a second conductivity type is provided on the first main surface side of the n-type silicon carbide epitaxial layer 2. In a first main surface side of the p-type base layer 6, an n⁺-type source region 7 of a first conductivity type and a p⁺⁺-type contact region 8 of the second conductivity type are provided. Further, the n⁺-type source region 7 and the p⁺⁺-type contact region 8 are in contact with each other. In a region of the surface layer of the n-type silicon carbide epitaxial layer 2 between the first p⁺-type base region 3 and the second p⁺-type base region 4 and in a region of the surface layer of the n-type silicon carbide epitaxial layer 2 between the p-type base layer 6 and the second p⁺-type base region 4, the dense n-type region 5 is provided. The dense n-type region 5 is formed to a position deeper than positions of the first p⁺-type base region 3 and the second p⁺-type base region 4.

In FIG. 1, although only two trench MOS structures are depicted, further trench MOS structures may be arranged in parallel.

On the entire first main surface side of the silicon carbide semiconductor base, an interlayer insulating film 11 is provided so as to cover the gate electrode 10 embedded in the trench 16. The source electrode 12 is in contact with the n⁺-type source region 7 and the p⁺⁺-type contact region 8, via a contact hole opened in the interlayer insulating film 11. The source electrode 12 is electrically insulated from the gate electrode 10 by the interlayer insulating film 11. On the source electrode 12, a source electrode pad 14 is provided.

Here, as dopants when the n⁺-type source region 7 is formed, two types, phosphorus and carbon, are co-implanted. A dose amount D_{C} of carbon at this time is set so that 0.7≤D_{C}/Dₚ≤1.3 is satisfied with respect to a dose amount Dₚ of phosphorus. As a result, the co-implanted carbon bonds with silicon that becomes surplus when the implanted phosphorus enters silicon sites in the silicon carbide, whereby silicon carbide is formed and interstitial atoms are reduced. When phosphorus alone is implanted, an atomic ratio of carbon and silicon in the silicon carbide is substantially equal in the n⁺-type source region 7. In contrast, by co-implanting phosphorus and carbon, the atomic ratio of carbon and silicon in the silicon carbide of the n⁺-type source region 7 is higher for carbon. At this time, the dose amount of phosphorus may be adjusted to a dose amount whereby an impurity concentration of the n⁺-type source region 7 is on an order of 10¹⁸ to 10²¹, and the n⁺-type source region 7 may be formed by multi-stage implantation. For example, the n⁺-type source region 7 is formed by multi-stage implantation using dose amounts of 2×10¹⁴, 1×10¹⁴, and 5×10¹³.

Further, as dopants when the n⁺-type source region 7 is formed, when two types, nitrogen and silicon, are co-implanted, a dose amount D_{Si} of silicon is set so the 0.7≤D_{Si}/D_{N}≤1.3 is satisfied with respect to a dose amount D_{N} of nitrogen. As a result, the co-implanted silicon bonds with carbon that becomes surplus when the implanted nitrogen enters carbon sites in the silicon carbide, whereby silicon carbide is formed and interstitial atoms are reduced. When nitrogen alone is implanted, an atomic ratio of carbon and silicon in the silicon carbide is substantially equal in the n⁺-type source region 7. In contrast, by co-implanting nitrogen and silicon together, the atomic ratio of carbon and silicon in the silicon carbide of the n⁺-type source region 7 is higher for silicon. At this time, the dose amount of nitrogen may be adjusted to a dose amount whereby the impurity concentration of the n⁺-type source region 7 is on the order of 10¹⁸ to 10²¹, and the n⁺-type source region 7 may be formed by multi-stage implantation. For example, the n⁺-type source region 7 may be formed by multi-stage implantation using dose amounts of 2×10¹⁴, 1.7×10¹⁴, 1.1×10¹⁴, and 1×10¹⁴. Since interstitial atoms may be reduced, it becomes possible to reduce drain saturation current (IDSS).

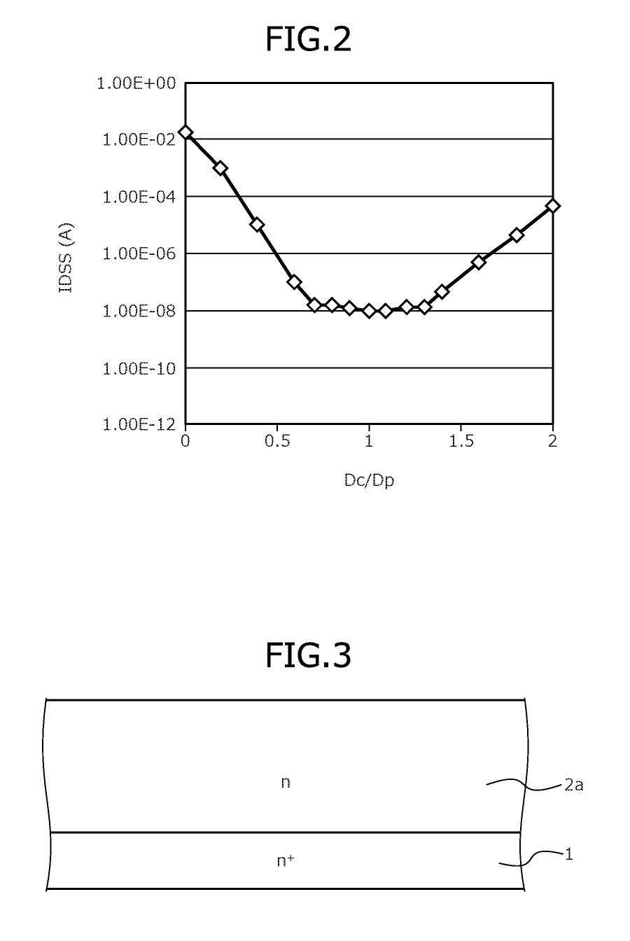

FIG. 2 is a graph depicting a relationship of drain saturation current (IDSS) and the ratio of Dₚ and D_{C} of the semiconductor device according to the embodiment. The relationship of IDSS and the ratio of Dₚ and D_{C} when two dopant types, phosphorus and carbon, are co-implanted in the formation of the n⁺-type source region 7 is depicted. It is found that interstitial atoms and IDSS decrease with an increased co-implantation dose amount of carbon. As for the dose amounts D_{C} and Dₚ, when set to satisfy 0.7≤D_{C}/Dₚ≤1.3, IDSS becomes at most 1×10⁻⁷ A. When the co-implantation dose amount of carbon is excessively increased, implantation damage, lattice defects, etc. are formed by implantation and therefore, increases in IDSS appear. Further, similar results are obtained when two dopant types, nitrogen and silicon, are co-implanted when the n⁺-type source region 7 is formed.

FIGS. 3, 4, 5, 6, 7, and 8 are cross-sectional views of the semiconductor device according to the embodiment during manufacture. Hereinafter, manufacturing processes of the silicon carbide semiconductor device depicted in FIG. 1 will be described sequentially. First, as depicted in FIG. 3, the n⁺-type silicon carbide substrate 1 containing an n-type silicon carbide is prepared. Subsequently, on a first main surface of the n⁺-type silicon carbide substrate 1, a first n-type silicon carbide epitaxial layer 2a containing silicon carbide is formed by epitaxial growth to have a thickness of, for example, about 10 μm while an n-type impurity, for example, nitrogen atoms, is doped. The first n-type silicon carbide epitaxial layer 2a is a part (lower layer) of the n-type silicon carbide epitaxial layer 2. The state up to here is depicted in FIG. 3.

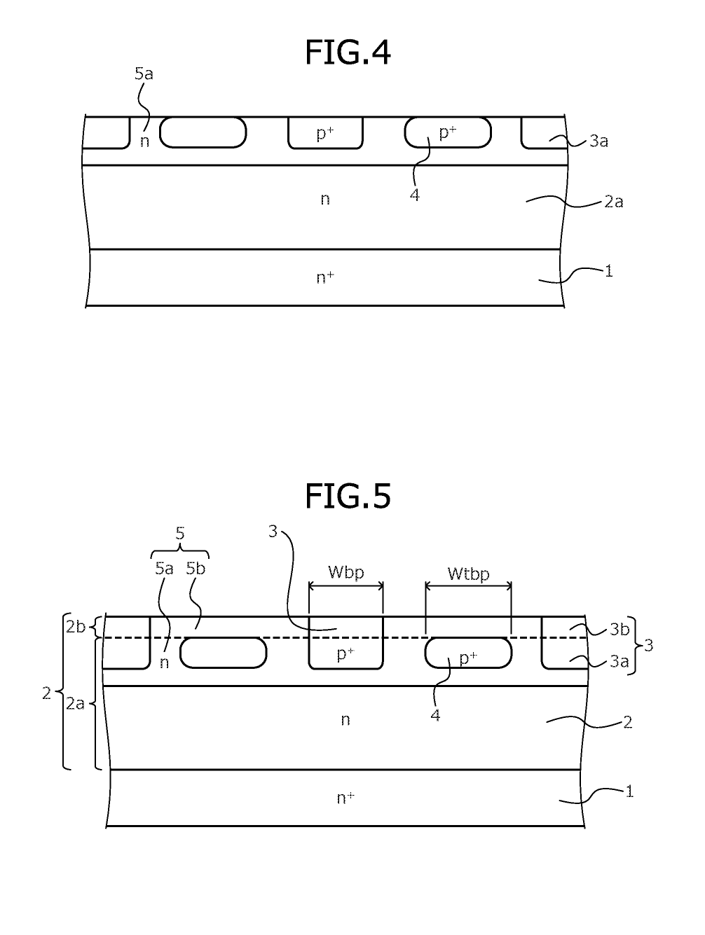

Next, as depicted in FIG. 4, on the surface of the first n-type silicon carbide epitaxial layer 2a, a non-depicted mask having predetermined openings is formed by a photolithography technique using, for example, an oxide film. Then, a p-type impurity, for example, aluminum atoms, is ion implanted by an ion implantation method. As a result, as depicted in FIG. 4, in parts of a surface region of the first n-type silicon carbide epitaxial layer 2a, for example, at a deep position of a depth of about 0.5 μm, a first p⁺-type base region 3a and the second p⁺-type base region 4 are formed so that, for example, a distance between the adjacent first p⁺-type base region 3a and second p⁺-type base region 4 is about 1 to 1.5 μm. At this time, the width Wbp of the first p⁺-type base region 3a is formed to be narrower than the width Wtbp of the second p⁺-type base region 4 (Wbp<Wtbp). As a result, electric field easily concentrates at the first p⁺-type base region 3a of the width Wbp that is narrower than that of the second p⁺-type base region, avalanche current flows to the first p⁺-type base region 3a, and the gate electrode 10 in the trench 16 is protected.

Further, the dose amount at the time of ion implantation for forming the first p⁺-type base region 3a and the second p⁺-type base region 4 may be set so that, for example, the impurity concentration becomes about 1×10¹⁸ to 1×10¹⁹/cm³. Next, the mask used at the time of the ion implantation for forming the first p⁺-type base region 3a and the second p⁺-type base region 4 is removed. Then, an n-type impurity, for example, nitrogen atoms, is ion implanted by an ion implantation method. As a result, as depicted in FIG. 4, in a part of a surface region of the first n-type silicon carbide epitaxial layer 2a, a dense n-type region 5a is formed to a position deeper than positions of the first p⁺-type base region 3a and the second p⁺-type base region 4. A dose amount at the time of ion implantation for forming the dense n-type region 5a deeply may be set so that, for example, the impurity concentration becomes about 5×10¹⁶ to 5×10¹⁷/cm³. The state up to here is depicted in FIG. 4.

Next, as depicted in FIG. 5, on the surface of the first n-type silicon carbide epitaxial layer 2a, a second n-type silicon carbide epitaxial layer 2b is formed by epitaxial growth to have a thickness of, for example, about 0.5 μm, while an n-type impurity, for example, nitrogen atoms, is doped. The second n-type silicon carbide epitaxial layer 2b and the first n-type silicon carbide epitaxial layer 2a together form the n-type silicon carbide epitaxial layer 2. Conditions of the epitaxial growth for forming the second n-type silicon carbide epitaxial layer 2b may be set so that, for example, an impurity concentration of the second n-type silicon carbide epitaxial layer 2b becomes about 8×10¹⁵/cm³.

Next, on the surface of the n-type silicon carbide epitaxial layer 2, a non-depicted mask having predetermined openings is formed by a photolithography technique using, for example, an oxide film. Then, a p-type impurity, for example, aluminum atoms, is ion implanted by an ion implantation method. As a result, as depicted in FIG. 5, in parts of a surface region of the n-type silicon carbide epitaxial layer 2, for example, a shallow first p⁺-type base region 3b at a depth of about 0.5 μm is formed overlapping a top of, for example, the (deep) first p⁺-type base region 3a. The shallow first p⁺-type base region 3b and the (deep) first p⁺-type base region 3a together form the p⁺-type base region 3. A dose amount at the time of the ion implantation for forming the shallow first p⁺-type base region 3b may be set so that, for example, the impurity concentration becomes about 1×10¹⁸ to 1×10¹⁹/cm³.

Next, the mask used at the time of the ion implantation for forming the shallow first p⁺-type base region 3b is removed. Then, an n-type impurity, for example, nitrogen atoms, is ion implanted by an ion implantation method. As a result, as depicted in FIG. 5, in a part of a surface region of the second n-type silicon carbide epitaxial layer 2b, a shallow dense n-type region 5b is formed at a depth of, for example, about 0.5 μm. A dose amount at the time of the ion implantation for forming the shallow dense n-type region 5b may be set so that, for example, the impurity concentration becomes about 5×10¹⁶ to 5×10¹⁷/cm³. The shallow dense n-type region 5b and the deep dense n-type region 5a together form the dense n-type region 5. The state up to here is depicted in FIG. 5.

Then, on the surface of the n-type silicon carbide epitaxial layer 2, the p-type base layer 6 is formed by epitaxial growth to have a thickness of, for example, about 0.7 to 1.3 μm while a p-type impurity, for example, aluminum atoms, is doped. Conditions of the epitaxial growth for forming the p-type base layer 6 may be set so that, for example, the impurity concentration becomes about 1×10¹⁶ to 5×10¹⁸/cm³.

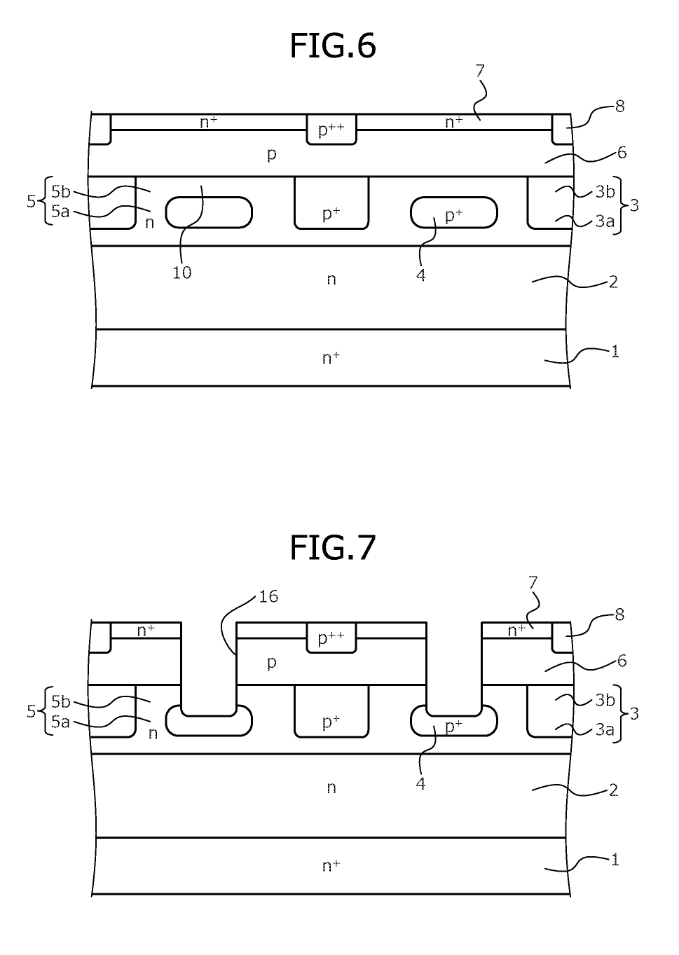

Next, on the surface of the exposed p-type base layer 6, a non-depicted mask having predetermined openings is formed by a photolithography technique using, for example, an oxide mask. Then, an n-type impurity, for example, phosphorus, is ion implanted by an ion implantation method. As a result, as depicted in FIG. 6, in parts of a surface region of the p-type base layer 6, the n⁺-type source region 7 is formed.

Here, as dopants at the time of formation of the n⁺-type source region 7, two types, phosphorus and carbon, are co-implanted using dose amounts whereby 0.7≤D_{C}/Dₚ≤1.3 is satisfied. Further, as dopants at the time of formation of the n⁺-type source region 7, when two types, nitrogen and silicon, are co-implanted, dose amounts are such that 0.7≤D_{Si}/D_{N}≤1.3 is satisfied. The dose amounts at the time of the ion implantation for the formation of the n⁺-type source region 7 may be set so that, for example, the impurity concentration becomes higher than that of the first p⁺-type base region 3.

Next, the mask used at the time of the ion implantation for forming the n⁺-type source region 7 is removed. Then, on the surface of the exposed p-type base layer 6, a non-depicted mask having predetermined openings formed by a photolithography technique using, for example, an oxide film is formed, and a p-type impurity, for example, aluminum is ion implanted in the surface of the p-type base layer 6. As a result, as depicted in FIG. 6, in parts of a surface region of the p-type base layer 6, the p⁺⁺-type contact region 8 is formed.

A dose amount at the time of the ion implantation for forming the p⁺⁺-type contact region 8 may be set so that, for example, the impurity concentration becomes higher than that of the second p⁺-type base region 4. Next, the mask used at the time of the ion implantation for forming the p⁺⁺-type contact region 8 is removed. The state up to here is depicted in FIG. 6.

Next, heat treatment (annealing) is performed and, for example, the first p⁺-type base region 3, the n⁺-type source region 7, and the p⁺⁺-type contact region 8 are activated. A temperature of the heat treatment may be, for example, about 1700 degrees C. A period of the heat treatment may be, for example, about 2 minutes. As described, ion implanted regions may be collectively activated by one session of heat treatment, or each time ion implantation is performed, the heat treatment may be performed to activate the ion implanted region.

Next, as depicted in FIG. 7, on the surface of the exposed p-type base layer 6, a non-depicted mask having predetermined openings is formed by a photolithography technique using, for example, an oxide mask. Then, by dry etching, the trenches 16 are formed penetrating the p-type base layer 6 and reaching the n-type silicon carbide epitaxial layer 2. The bottoms of the trenches 16 may reach the second p⁺-type base regions 4, or may be formed in the n-type silicon carbide epitaxial layer 2 between the p-type base layer 6 and the second p⁺-type base regions 4. Next, the mask used for forming the trenches 16 is removed. The state up to here is depicted in FIG. 7.

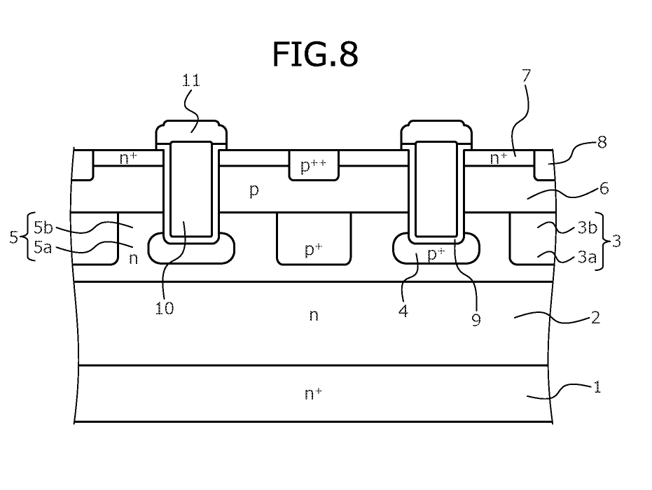

Next, as depicted in FIG. 8, the gate insulating film 9 is formed at the bottom and the sides of each trench 16, along the surface of the trench 16 at the n⁺-type source region 7 and the p⁺⁺-type contact region 8. The gate insulating film 9 may be formed by thermal oxidation of an oxide film by heat treatment at 1000 degrees C. in an oxygen atmosphere. Further, the gate insulating film 9 may be formed by a deposition method by a chemical reaction such as for a high temperature oxide (HTO).

Next, on the gate insulating film 9, a polycrystalline silicon layer doped with, for example, phosphorus atoms, is formed. The polycrystalline silicon layer may be formed so as to be embedded in the trenches 16. The polycrystalline silicon layer is patterned and parts in the trenches 16 are left to remain, whereby the gate electrode 10 is formed in each trench 16. A part of the gate electrode 10 may protrude outside the trench 16.

Next, for example, phosphorus glass is deposited so as to cover the gate insulating film 9 and the gate electrode 10, and have a thickness of about 1 μm, whereby the interlayer insulating film 11 is formed. The interlayer insulating film 11 and the gate insulating film 9 are patterned and selectively removed, whereby a contact hole is formed, exposing the n⁺-type source region 7 and the p⁺⁺-type contact region 8. Thereafter, heat treatment (reflow) is performed and the interlayer insulating film 11 is planarized. The state up to here is depicted in FIG. 8.

Next, in the contact hole and on the interlayer insulating film 11, a conductive film constituting the source electrode 12 is formed. The conductive film is selectively removed, leaving, for example, the source electrode 12 only in the contact hole.

Next, on a second main surface of the n⁺-type silicon carbide substrate 1, for example, the rear electrode 13 constituted by a nickel film is formed. Thereafter, for example, heat treatment at a temperature of about 970 degrees C. is performed, forming an ohmic junction of the n⁺-type silicon carbide substrate 1 and the rear electrode 13.

Next, as depicted in FIG. 1, for example, an aluminum film is formed, for example, by a sputtering method, so as to cover the source electrode 12 and the interlayer insulating film 11, and have a thickness of, for example, about 5 μm. Thereafter, the aluminum film is selectively removed so that a part thereof covering an element overall remains, whereby the source electrode pad 14 is formed.

Next, on a rear surface of the rear electrode 13, for example, titanium, nickel, and gold are sequentially stacked in stated order, whereby a drain electrode pad 15 is formed. Thus, as described, the semiconductor device depicted in FIG. 1 is completed.

According to the described embodiment, two dopant types, phosphorus and carbon, are co-implanted when the n⁺-type source region 7 is formed, the dose amount D_{C} of carbon is set so that 0.7≤D_{C}/Dₚ≤1.3 is satisfied with respect to the dose amount Dₚ of phosphorus. As a result, the co-implanted carbon bonds with silicon that becomes surplus when the implanted phosphorus enters silicon sites in the silicon carbide, forming silicon carbide and reducing interstitial atoms. Further, when two dopant types, nitrogen and silicon, are used when the n⁺-type source region 7 is formed, the dose amount D_{Si} of silicon is set so that 0.7≤D_{Si}/D_{N}≤1.3 is satisfied with respect to the dose amount D_{N} of nitrogen. As a result, the co-implanted silicon bonds with carbon that becomes surplus when the implanted nitrogen enters carbon sites in the silicon carbide, forming silicon carbide and reducing interstitial atoms. Since interstitial atoms may be reduced it becomes possible to reduce drain saturation current (IDSS), enabling generation of leak current to be suppressed.

In the embodiment, although formation of the shallow dense n-type region 5b is depicted to be performed by ion implantation, an impurity concentration of nitrogen at the time of epitaxial growth of the second n-type silicon carbide epitaxial layer 2b may be set to be about 5×10¹⁶ to 5×10¹⁷/cm³ and the method of manufacturing may omit the ion implantation.

In the embodiment of the present invention, as an example, a case is described in which a main surface of the silicon carbide substrate containing silicon carbide is assumed to be a (0001) plane and on the (0001) plane, a MOS is configured, however, without limitation to the plane orientation and the MOS, various modifications such as in the plane orientation of the substrate main surface and the elements having an n-type region such as an IGBT, a SIT, etc. are possible.

Further, in the embodiment, the first conductivity type is assumed to be an n-type and the second conductivity type is assumed to be a p-type.

According to the embodiment of the present invention, crystal defects and particularly, interstitial atoms are suppressed, and generation of leak current may be suppressed.

As described, the semiconductor device according to the embodiment of the present invention is useful for high-voltage semiconductor devices used in power converting equipment, and in power supply devices used in various industrial machines.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a silicon carbide semiconductor substrate of the first conductivity type having a high impurity concentration;
a first silicon carbide semiconductor layer of a first conductivity type formed on a surface of the silicon carbide semiconductor substrate of the first conductivity type, the first silicon carbide semiconductor layer having a low impurity concentration;
a first base region of a second conductivity type selectively provided in a surface of the first silicon carbide semiconductor layer;
a second silicon carbide semiconductor layer of the second conductivity type formed on the first silicon carbide semiconductor layer;
a source region of the first conductivity type and a contact region of the second conductivity type formed selectively in a surface layer of the second silicon carbide semiconductor layer;
a trench formed to penetrate the second silicon carbide semiconductor layer;
a gate insulating film formed in the trench; and
a gate electrode formed in the trench on the gate insulating film,
wherein the source region is formed using two dopant types that are phosphorus and carbon, a dose amount, D_{C}, of carbon satisfying 0.7≤D_{C}/Dₚ≤1.3 with respect to a dose amount, Dₚ, of phosphorus, and the source region having an impurity concentration ranging from 10¹⁸ to 10²¹.

2. The semiconductor device according to claim 1, further comprising a first-conductivity-type region of the first conductivity type formed between the first silicon carbide semiconductor layer and the second silicon carbide semiconductor layer, the first-conductivity-type region having an impurity concentration that is higher than that of the first silicon carbide semiconductor layer,
wherein the first base region has a lower end which is in the first-conductivity-type region and the trench has a lower end which is in the first-conductivity-type region.

3. The semiconductor device according to claim 1, wherein the source region contains carbon and silicon, and the source region has a higher ratio of carbon than silicon.

4. A semiconductor device, comprising:
a silicon carbide semiconductor substrate of the first conductivity type having a high impurity concentration;
a first silicon carbide semiconductor layer of a first conductivity type formed on a surface of the silicon carbide semiconductor substrate of the first conductivity type, the first silicon carbide semiconductor layer having a low impurity concentration;
a first base region of a second conductivity type selectively provided in a surface of the first silicon carbide semiconductor layer;
a second silicon carbide semiconductor layer of the second conductivity type formed on the first silicon carbide semiconductor layer;
a source region of the first conductivity type and a contact region of the second conductivity type formed selectively in a surface layer of the second silicon carbide semiconductor layer;
a trench formed to penetrate the second silicon carbide semiconductor layer;
a gate insulating film formed in the trench; and
a gate electrode formed in the trench on the gate insulating film,
wherein the source region is formed using two dopant types that are nitrogen and silicon, a dose amount, D_{Si}, of silicon satisfying 0.7≤D_{Si}/D_{N}≤1.3 with respect to a dose amount, D_{N}, of nitrogen, and the source region has an impurity concentration ranging from 10¹⁸ to 10²¹.

5. The semiconductor device according to claim 4, wherein the source region contains silicon and carbon, and the source region has a higher ratio of silicon than carbon.

6. The semiconductor device according to claim 1, further comprising a second base region of the second conductivity type provided at a lower end of the trench, the second base region having an impurity concentration that is equal to that of the first base region,
wherein the first base region has a width, Wbp, and the second base region has a width, Wtbp, and the width, Wbp, of the first base region is narrower than the width, Wtbp, of the second base region so that Wbp<Wtbp.

7. A method of manufacturing a semiconductor device, the method comprising:
providing a silicon carbide semiconductor substrate of the first conductivity type having a high impurity concentration;
forming a first silicon carbide semiconductor layer of a first conductivity type on a surface of the silicon carbide semiconductor substrate of the first conductivity type, the first silicon carbide semiconductor layer having a low impurity concentration;
selectively forming a first base region of a second conductivity type and a second base region of the second conductivity type in a surface layer of the first silicon carbide semiconductor layer;
forming a second silicon carbide semiconductor layer of the second conductivity type on a surface of the first silicon carbide semiconductor layer, the second silicon carbide semiconductor layer having a low impurity concentration;
selectively forming a source region of the first conductivity type in a surface of the second silicon carbide semiconductor layer;
forming a contact region of the second conductivity type in the surface of the second silicon carbide semiconductor layer, the contact region being adjacent to the source region;
forming a trench at a part of the source region in the surface of the second silicon carbide semiconductor layer, the trench penetrating the second silicon carbide semiconductor layer, being shallower than the second base region, and having a bottom and sides;
forming a gate insulating film on the bottom and the sides of the trench;
forming a gate electrode on the gate insulating film;
forming an interlayer insulating film on the gate electrode;
forming a source electrode on surfaces of the source region and the contact region; and
forming a drain electrode on a rear surface of the silicon carbide semiconductor substrate,
wherein forming the source region includes using two dopant types that are phosphorus and carbon, a dose amount, D_{C}, of carbon satisfying 0.7≤D_{C}/Dₚ≤1.3 with respect to a dose amount, Dₚ, of phosphorus, and the source region has an impurity concentration ranging from 10¹⁸ to 10²¹.

8. The method of manufacturing a semiconductor device according to claim 7, further comprising forming a first-conductivity-type region of the first conductivity type, the first-conductivity-type region being formed deeper than the first base region and the second base region from the surface of the second silicon carbide semiconductor layer.

9. A method of manufacturing a semiconductor device, the method comprising:
providing a silicon carbide semiconductor substrate of the first conductivity type having a high impurity concentration;
forming a first silicon carbide semiconductor layer of a first conductivity type on a surface of the silicon carbide semiconductor substrate of the first conductivity type, the first silicon carbide semiconductor layer having a low impurity concentration;
selectively forming a first base region of a second conductivity type and a second base region of the second conductivity type in a surface layer of the first silicon carbide semiconductor layer;
forming a second silicon carbide semiconductor layer of the second conductivity type on a surface of the first silicon carbide semiconductor layer, the second silicon carbide semiconductor layer having a low impurity concentration;
selectively forming a source region of the first conductivity type in a surface of the second silicon carbide semiconductor layer;
forming a contact region of the second conductivity type in the surface of the second silicon carbide semiconductor layer, the contact region being adjacent to the source region;
forming a trench at a part of the source region in the surface of the second silicon carbide semiconductor layer, the trench penetrating the second silicon carbide semiconductor layer, being shallower than the second base region, and having a bottom and sides;
forming a gate insulating film on the bottom and the sides of the trench;
forming a gate electrode on the gate insulating film;
forming an interlayer insulating film on the gate electrode;
forming a source electrode on surfaces of the source region and the contact region; and
forming a drain electrode on a rear surface of the silicon carbide semiconductor substrate,
wherein forming the source region includes using two dopant types that are nitrogen and silicon, a dose amount, D_{Si}, of silicon satisfies 0.7≤D_{Si}/D_{N}≤1.3 with respect to a dose amount, D_{N}, of nitrogen, and the source region has an impurity concentration ranging from 10¹⁸ to 10²¹.

10. The method of manufacturing a semiconductor device according to claim 9, further comprising forming a first-conductivity-type region of the first conductivity type, the first-conductivity-type region being formed deeper than the first base region and the second base region from the surface of the second silicon carbide semiconductor layer.
